(19) United States
(12) Patent Application Publication
(10) Pub. No.: US 2015/0370014 A1
(43) Pub. Date: Dec. 24, 2015

(54) METHODS AND APPARATUS TO REMOVE DUST FROM AN OPTICAL WAVEGUIDE ASSEMBLY

(71) Applicant: HEWLETT-PACKARD DEVELOPMENT COMPANY, Houston, TX (US)

(72) Inventors: Kian Teck POH, Singapore (SG); Chee How Lee, Singapore (SG); Jing Kai TAN, Singapore (SG)

(21) Appl. No.: 14/763,136

(22) PCT Filed: Jan. 24, 2013
(86) PCT No.: PCT/US2013/022989

§ 371 Date: Jul. 23, 2015

(51) Int. Cl. G02B 6/10; B08B 7/02; H01L 41/47; H01L 41/09

(52) U.S. Cl. CPC G02B 6/10; H01L 41/09; B08B 7/02; H01L 41/47

(57) ABSTRACT

Example methods and apparatus to remove dust from an optical waveguide assembly are disclosed. An example apparatus includes a window to be located on an optical waveguide assembly. The example apparatus includes a first piezoelectric member coupled to the window. The first piezoelectric member is to vibrate the window to remove dust from the window in response to an electrical signal.

### BACKGROUND

In telecommunications, such as computer networking, the bandwidth requirements for network switches that link different network segments and/or network devices are continually increasing. To meet these demands, developers have turned to photonics and the establishment of optical communication paths to transmit data.

### BRIEF DESCRIPTION OF THE DRAWINGS

FIG. 1 is a perspective view of a known network switch system showing a portion of an optical waveguide assembly to serve as an optical backplane to support multiple line cards.

FIG. 2 is an exploded view of an example system 200 constructed in accordance with teachings disclosed herein.

FIG. 3 is a partially cut-away view of the example system of FIG. 2 in assembled form.

FIG. 4 is a cross-sectional view of the example system of FIG. 3.

FIG. 5 is a close-up of a portion of the cross-sectional view of the example dust-removing apparatus of FIG. 4.

FIG. 6 is cross-sectional view of another example system constructed in accordance with teachings disclosed herein.

FIG. 7 is cross-sectional view of another example system constructed in accordance with the teachings disclosed herein.

FIG. 8 is a flowchart representative of example machine readable instructions which may be executed to remove dust from an optical waveguide assembly.

FIG. 9 is a flowchart representative of an example method of manufacturing the example systems 200, 600, 700 described in connection with FIGS. 2-7.

FIG. 10 illustrates an example method of retrofitting an optical waveguide assembly with a dust-removing apparatus such as the apparatus of FIGS. 2-7.

FIG. 11 illustrates an example method detailing the mounting process of the dust-removing apparatus on to a waveguide assembly of the example process of FIG. 10.

FIG. 12 is a schematic illustration of an example processor platform that may be used and/or programmed to execute any of the example machine readable instructions of FIG. 8 to implement the example dust-removing apparatus of FIGS. 2-7.

### DETAILED DESCRIPTION

Through the implementation of an optical backplane on a network switch chassis, a bandwidth approximately ten times that of a comparable electrical network switch may be achieved. However, establishing a line of sight between optical emitters and receivers over optical communication paths is important to ensure the optical interconnect system functions properly. Establishing such a line of sight includes achieving mechanical alignment of optical components and ensuring that there are no obstructions blocking the path of the optical signals. Even a small speck of dust within the line of sight can impact the transmission of data associated with an optical signal.

When optical connectors are in engagement, the concern of dust blocking the path of an optical signal is relatively small as the connection of the optical devices can keep dust and/or other foreign particles from getting in the way. However, in certain situations, an optical connector may be left free or open to a surrounding environment, thereby giving rise to the potential for the accumulation of dust. For example, a telecommunications network may be serviced by multiple network switches (e.g., line cards) connected via a common backplane of a network switch chassis. In some such examples, the backplane may have more slots than are being used by the multiple network switches. Over time the unused slots will accumulate dust including dust that will settle directly on the connection points where a path of an optical signal would pass if the slot was being used. While such dust may have little effect on electrical connections made via a copper backplane, the dust can detrimentally impact the effectiveness of an optical connection via the optical backplane when the slot is to be used at a later time. Example dust-removing apparatus disclosed herein overcome this obstacle by shaking off any accumulated dust in the path of an optical signal to ensure a clear line of sight.

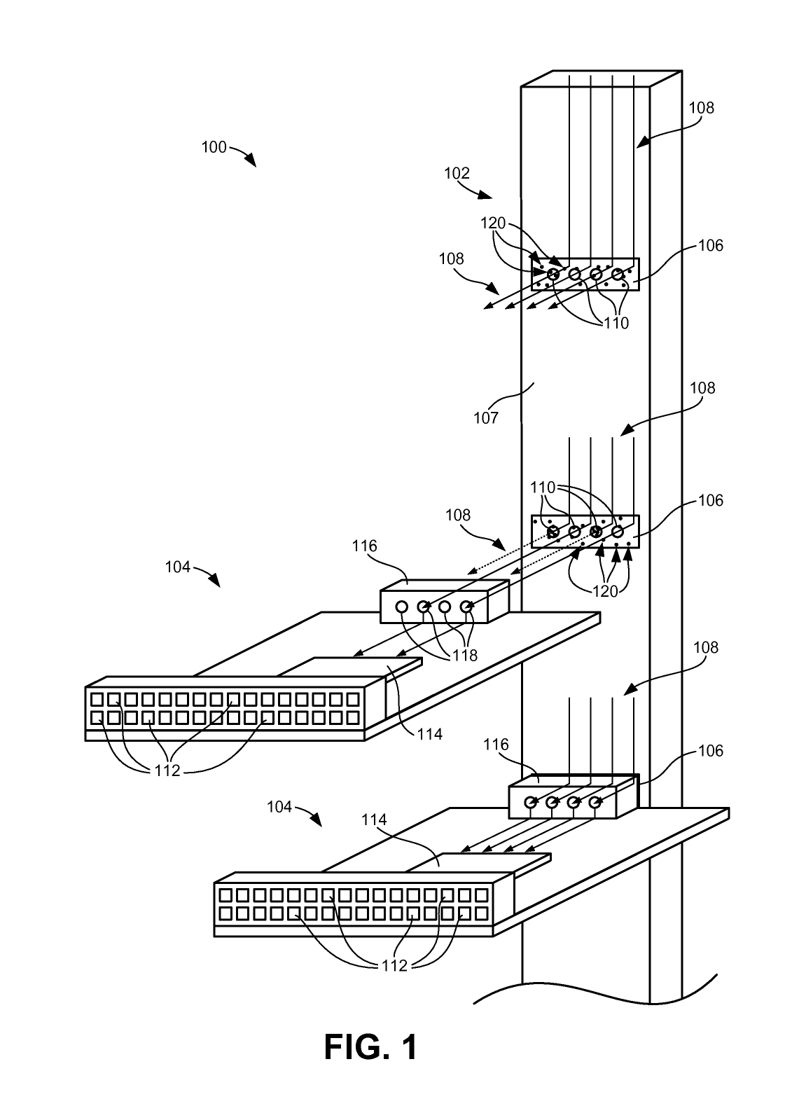

FIG. 1 is a perspective view of a known network switch system 100 showing a portion of an optical waveguide assembly 102 serving as an optical backplane for multiple network blades or line cards 104. For convenience and brevity, as used herein, the terms “optical waveguide” or just “waveguide” are used interchangeably. The term “optical waveguide assembly” refers to one or more elements at least one of which is a waveguide. In other words, a “waveguide” is one component in a “waveguide assembly” that may also include one or more components (e.g., a casing, a frame, a cover, an internally disposed gold-coated Mylar® cover, mirrors, beam splitters (e.g., pellicle beam splitters) positioned within the waveguide, and/or optical windows to seal off the waveguide while allowing optical signals to pass in and/or out of the waveguide as directed by the splitters and/or mirrors).

The optical waveguide assembly 102 of FIG. 1 is known in the art. The optical waveguide 102 includes multiple optical windows 106 inset within an opening or recess of a housing or frame 107 of the waveguide assembly 102. In FIG. 1, each optical window 106 is associated with a beam splitter within the waveguide 102. Each beam splitter is positioned such that as an optical signal (e.g., represented by the arrows 108) is transmitted down the waveguide 102, at least a portion of the optical signal 108 is deflected out of the waveguide 102 through the corresponding optical window 106. In the illustrated example, the cross-sectional areas of the path of the optical signals 108 at the places in which the optical signals 108 pass through the optical windows 106 are shown by the circles 110.

The line cards 104 of FIG. 1 are constructed to engage the optical waveguide assembly 102 to receive corresponding ones of the optical signals 108. In particular, as shown in FIG. 1, each network blade or line card 104 includes a series of network ports 112 (e.g., RJ45 ports), a node chip 114, and an optical connector 116. The optical connectors 116 of FIG. 1 are optical receivers that interface with a corresponding one of the optical windows 106 (as shown with the bottom network blade 104 in FIG. 1) to receive and/or transfer the optical signals 108 to and/or from the waveguide assembly 102. In some examples, the optical connector 116 is an optical receiver and an optical emitter to both receive and transmit optical signals to and/or from the optical waveguide assembly 102. In other examples, a separate optical transmitter is provided to interface with a separate optical waveguide assembly for a return path. In the illustrated example, once the optical connector 116 detects the optical signal(s) 108, the optical connector converts the signal(s) into electrical signal(s) and passes the electrical signal(s) on to the node chip 114 via connections 118. The node chip 114 passes the electric signal(s) on to the network ports 112 (or vice versa for the return path) as appropriate.

In some situations, the network switch system 100 includes more slots on the backplane (e.g., optical windows 106 on the waveguide 102) than line cards 104 being used to serve a corresponding network. While free or open slots do not impact the functionality of the network switch system 100, leaving the corresponding optical windows 106 exposed can collect dust resulting in a poor connection when an additional network blade 104 is added to the network switch system 100 at a later time by interfering with the connection at the window(s) that were previously exposed. In FIG. 1, the upper most optical window 106 is not engaged by a network blade 104 (i.e., the uppermost optical window 106 corresponds to an open slot in the network switch system 100). In the illustrated example, due to the exposure of the uppermost optical window 106 to the surrounding environment, as time passes, dust and/or other particles 120 accumulate and settle on the optical window 106. In some examples, the dust 120 accumulates on the optical window 106 within the path 110 of the optical signal 108. As a result, in some examples, the dust 120 blocks (partially or fully), attenuates, and/or otherwise effects the transmission of the optical signal 108 as it passes through the optical window 106. Based upon the obstruction of the optical signal 108 by the dust 120, if a network blade 104 is subsequently added to the waveguide 102 to interface with the soiled optical window 106, the dust 120 may hinder the establishment of a clear line of sight for the proper transmission of the optical signal 108.

For example, the upper network blade 104 of FIG. 1 is shown to be interfacing with the middle optical window 106. In the illustrated example, the upper network blade 106 is shown separated from the optical window 106 for the purposes of this explanation but, when in actual use, would be engaged with the middle optical window 106 as is shown for the bottom network blade 104 in the illustrated example. In the illustrated example, the upper network blade 104 receives only a portion of the corresponding optical signal 108 passing through the corresponding optical window 106, which is then passed on to the node chip 114 as described above. Only a portion of the optical signal 108 is detected by the optical connector 116 of the upper network blade 104 because the remaining portions of the optical signal 108 have been blocked by the accumulation of dust 120 over one or more of the paths 110 of the optical signals 108 of the optical window 106. If the soiling is severe enough, the optical connector 116 will be unable to detect the correct optical signal 108 and the example network switch system 100 will not work properly.

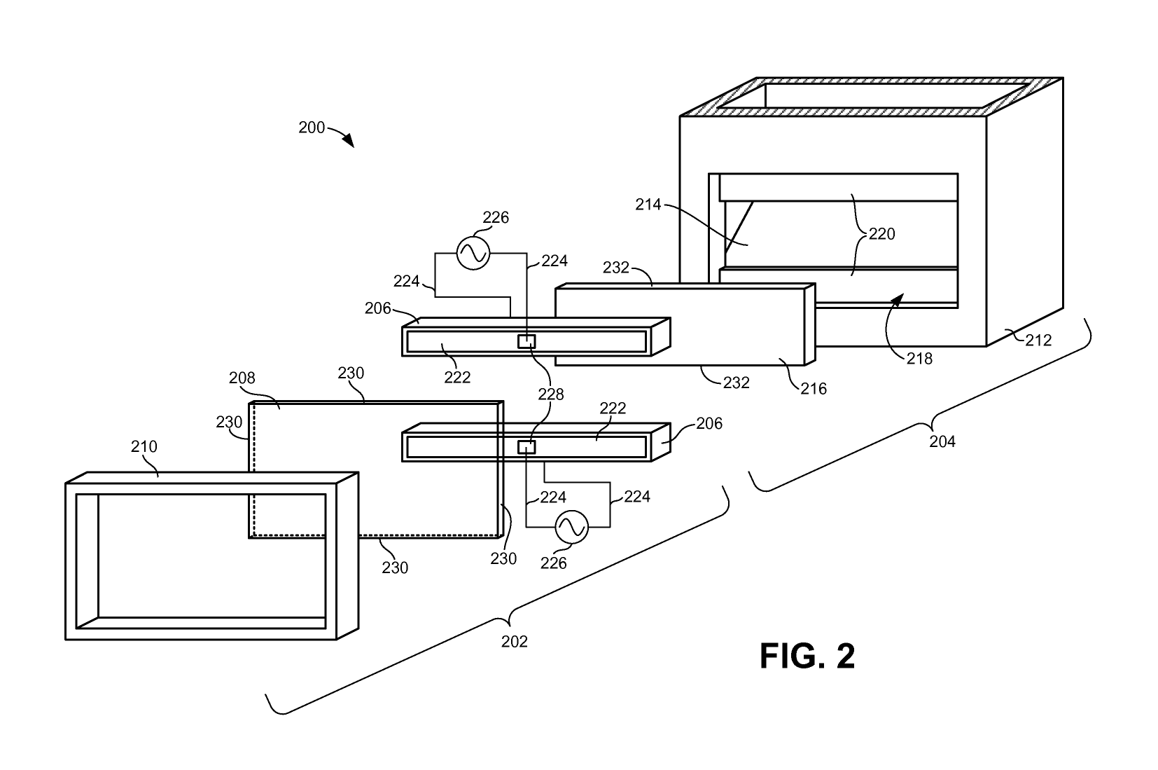

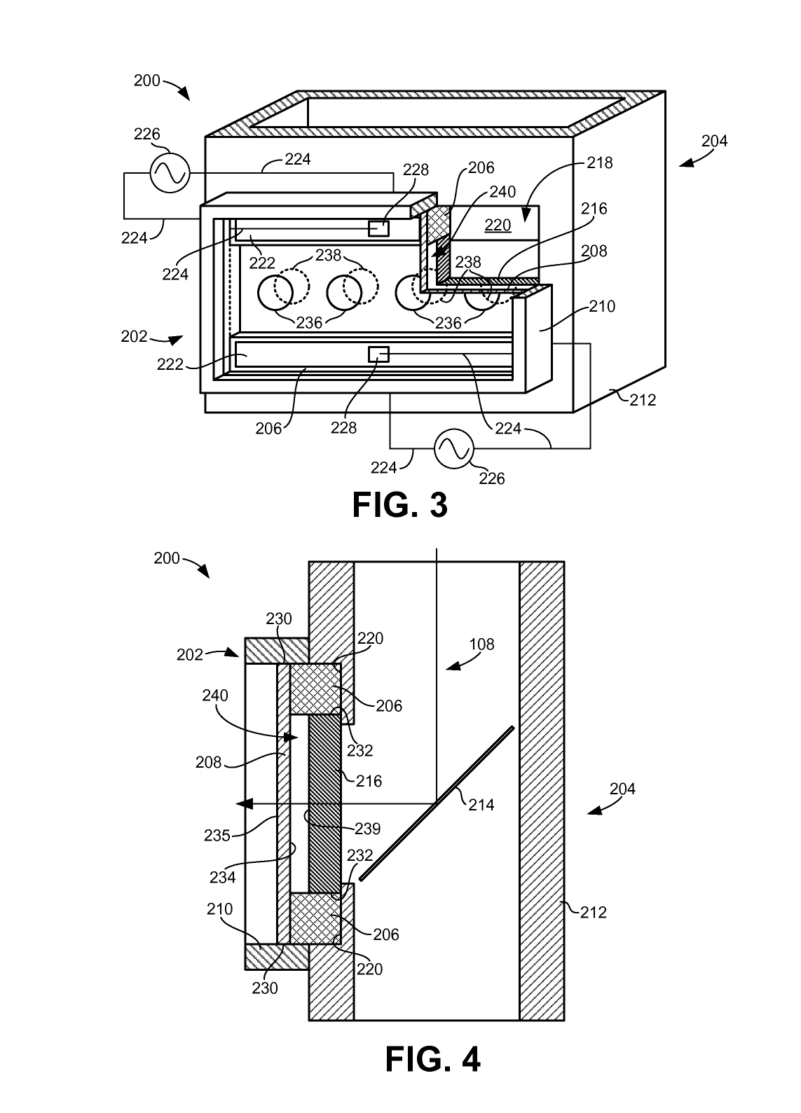

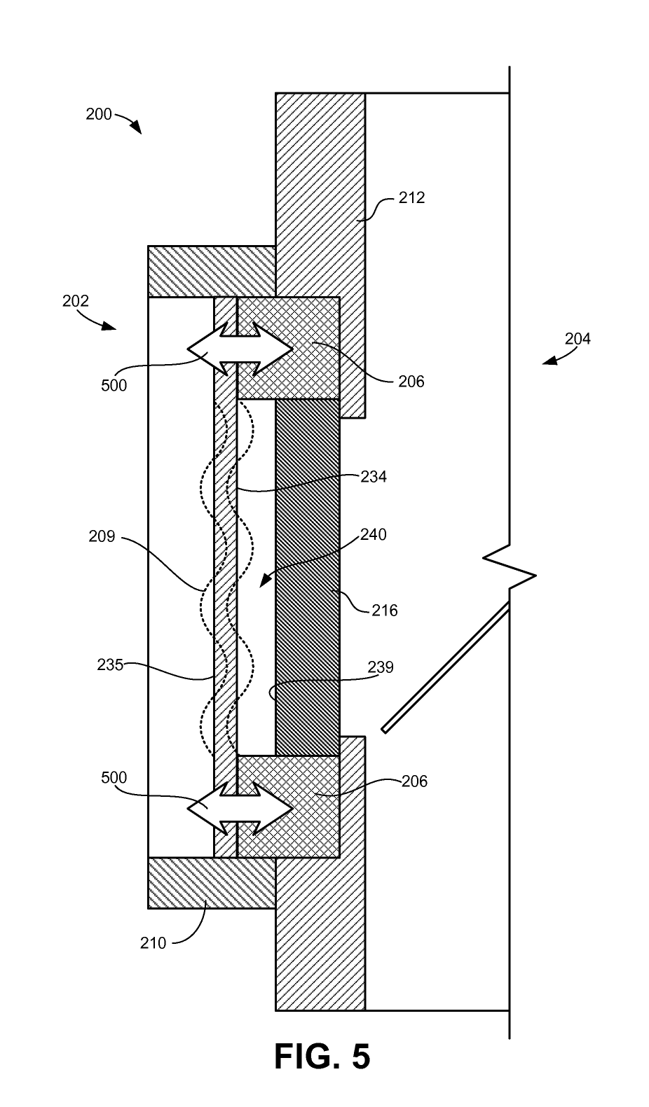

FIGS. 2-5 illustrate an example system 200 constructed in accordance with teachings of this disclosure to overcome the dust accumulation problem described above. In some examples, the system 200 includes an example dust-removing apparatus 202 coupled to an example optical waveguide assembly 204. FIG. 2 is an exploded view of an example dust-removing apparatus 202 and the optical waveguide 204 of the example system 200. FIG. 3 is a partially cut-away view of the example system 200 of FIG. 2 in assembled form. FIG. 4 is a cross-sectional view of the example system 200 of FIG. 2. FIG. 5 is a close-up view of a portion of the cross-sectional view of FIG. 4.

The example dust-removing apparatus 202 of the illustrated examples includes two piezoelectric members 206, a dust-removing sheet 208, and a frame 210. The example optical waveguide assembly 204 of the illustrated example includes a housing 212 within which is a beam splitter 214 (e.g., a pellicle beam splitter). In the illustrated example, the optical waveguide 204 also includes an optical window 216 that is to be situated within a recess 218 of the housing 212 near a back wall 220 of the recess 218. In some examples, the optical window 216 is the same as any one of the optical windows 106 described above in connection with FIG. 1. The waveguide assembly 204 may be similar to the waveguide assembly 102 of FIG. 1. However, a difference between the optical waveguide 204 of FIG. 2 and the optical waveguide 102 of FIG. 1 is the dimensions of the recess 218 of the housing 212. In particular, the recess 218 is physically dimensioned to provide space to enable the piezoelectric members 206 to be disposed, along with and adjacent to the window 216, within the recess 218 in front of the back wall 220 as shown in FIG. 4.

Due to the electromechanical properties of the piezoelectric members 206, the piezoelectric members 206 of the illustrated example change shape when subjected to an electric field or current. Accordingly, in some examples, conductive plates 222 are affixed to opposing sides of each piezoelectric member 206 and wires 224 from a power source 226 are attached to leads 228 connected to each conductive plate 222. In some examples, an electrical voltage and/or current from the power source 226 is applied across the piezoelectric members 206 to cause them to change shape in accordance with the electrical signal. In some such examples, the voltage and/or current varies at a frequency to cause the piezoelectric members 206 to vibrate. In some examples, the applied electrical voltage and/or current is the same for both piezoelectric members 206. In some such examples, the frequency at which the electric voltage and/or current for one of the piezoelectric member 206 varies is out of phase with frequency of the electric voltage and/or current for the other piezoelectric member 206. In other examples, the electrical voltage and/or current for each piezoelectric member 206 is different. In the illustrated example, the electrical voltage and/or current are provided by the same power source. However, other examples use more than one power source (e.g., different power sources for different ones of the piezoelectric members 206).

Although two piezoelectric member 206 are used in the example of FIG. 2, other numbers (1, 3, 4, etc.) of such members 206 could alternatively be employed. In some examples, the piezoelectric members 206 are affixed (e.g., via an adhesive) to the example dust-removing sheet 208 of the example dust-removing apparatus 202. As shown most clearly in the illustrated example of FIG. 4, when assembled, the piezoelectric members 206, of the illustrated example, are affixed adjacent opposing edges 230 of the sheet 208 on the same inner or back surface 234 of the sheet 208 facing the example optical waveguide assembly 204. In the illustrated example, the combined assembly of the piezoelectric members 206 and the dust-removing sheet 208 are disposed over the optical window 216. Further, each piezoelectric member 206 of the illustrated example is affixed (e.g., via an adhesive) to the housing 212 adjacent opposing sides or edges 232 of the optical window 216 and the opposing edges 230 of the dust-removing sheet 208. In this manner, the piezoelectric members 206 hold the sheet 208 across the optical window 216 to cover the optical window 216 from exposure to the surrounding environment and protect it from the accumulation of dust and/or other particles (e.g., the dust 120 of FIG. 1). The sheet 208 employed in the illustrated example is discussed further below.

In some examples, one side of the piezoelectric members 206 is affixed to the sheet 208 and a second side of the piezoelectric members 206 is affixed to the back wall 220 of the housing 212. The remaining sides of the piezoelectric members 206 remain unattached to the surrounding structure to allow the piezoelectric members 206 to change shape when subject to an electric voltage and/or current as shown in FIG. 5. FIG. 5 illustrates example movement (represented by the arrows 500) of the piezoelectric members 206 of the example system of FIGS. 2-4 when vibrating under the application of an alternating electric signal. In the illustrated example, the piezoelectric members 206 are configured to primarily move (e.g., expand and/or contract) in a direction substantially normal to the inner surface 234 of the sheet 208. In some examples, the position of rest for the piezoelectric members 206 (i.e., when the piezoelectric members 206 are not subject to an electric force) defines one of the extremities of movement of the piezoelectric members 206. For example, when an electric force is applied, the piezoelectric members 206 may extend outward and then return to a more contracted rest position when the electric signal is removed. Alternatively, an applied electric force, in some examples, causes the piezoelectric members 206 to contract inward before expanding to a more expanded shape associated with the rest position of the piezoelectric members 206 when no electric force is applied. In other examples, the position of rest for the piezoelectric members 206 may be at any other location between an inner and outer extremity of the piezoelectric members 206 when oscillating back and forth in the direction of movement identified by the arrows 500. As shown in the illustrated example of FIG. 5, while there may be some change of shape of the piezoelectric members 206 within the plane of the optical window 216, the piezoelectric members 206 are configured to vibrate (e.g., change shape) primarily in-and-out with respect to the optical window 216 in the direction indicated by the arrows 500. In this manner, the surrounding components (e.g., the frame 210 and/or housing 212) do not interfere with the vibration of the piezoelectric members 206 and/or cause wear to the example system 200.

In some examples, the sheet 208 is made of a thin plastic material that is flimsy or flexible (e.g., capable of vibrating and/or oscillating when shaken) such that the force of vibration of the piezoelectric members 206 under an applied electrical signal transfers to the sheet 208 causing it to oscillate and/or vibrate as indicated in FIG. 5 by the wavy dashed lines 209. In this manner, any dust that accumulates or settles on the outside of the sheet 208 (e.g., on an outer or front surface 235 opposite the inner surface 234 of the sheet 208) will be shaken off to maintain a clear line of sight for an optical signal (e.g., the optical signal 108 of FIG. 1) to be transmitted to and/or from the waveguide 204. Accordingly, as shown in the illustrated example, the dust-removing sheet 208 is made of a material that is optically transparent at the frequency of the signals to be carried by the waveguide 204 so as not to obstruct the path(s) (e.g., represented by the solid circles 236 in FIG. 3) of the optical signal(s) 108 as the optical signal(s) 108 pass through the sheet 208. The optical window 216 is also transparent to the signal(s).

In the illustrated example, the piezoelectric members 206 are dimensioned to protrude away from the optical waveguide assembly 204 a distance beyond an outer surface 239 of the optical window 216 to hold the sheet 208 away from the optical window 216 (e.g., to create a gap or clearance 240 between the inner surface 234 of the sheet 208 and the outer surface 239 of the optical window 216). In this manner, as the piezoelectric members 206 are vibrated, the sheet 206 will also be able to freely vibrate without interference from the optical window 216 as shown in the illustrated example of FIG. 5.

In some examples, the frame 210 is affixed (e.g., via an adhesive) to the housing 212 of the optical waveguide 212 to surround a perimeter of the dust-removing sheet 208 defined by the edges 230 of the dust-removing sheet 208. The frame 210, thus, blocks dust from getting past the sheet 208 and into the gap 240 (e.g., via the edges 230 not attached to the piezoelectric members 206). Accordingly, in some examples, the frame 210 is dimensioned with precise tolerances (e.g., +/−1%) to closely fit around the sheet 208 without significantly affecting the free vibration of the piezoelectric members 206 and the sheet 208.

Numerous variations to the example system 200 described above may be implemented in accordance with the teachings disclosed herein. For example, while the illustrated examples identify the edges 230 associated with the piezoelectric members 206 as running along the top and bottom of the sheet 208, in other examples, the piezoelectric members 206 are attached along the side edges of the sheet 208. Additionally, the examples described herein are not limited to two piezoelectric members 206. In some examples, fewer or more than two piezoelectric members 206 are attached to the dust-removing sheet 208. Further, the physical dimensions of the piezoelectric members 206 relative to the sheet 208 may be suitably varied. For instance, in the example shown in FIGS. 2 and 3, the piezoelectric members 206 are approximately the same length as the dust-removing sheet 208. In other examples, the piezoelectric member(s) is/are shorter than the dust-removing sheet 208. In some examples, only a single piezoelectric member 206 is used. In some such examples, the opposing edge 230 of the sheet 208 which is not connected to the single piezoelectric member 206 is affixed to any of the housing 212 of the optical waveguide assembly 204 or the frame 210. Furthermore, in the illustrated example, the piezoelectric members 206 are affixed to both the sheet 208 and the housing 212. Accordingly, in some examples, the frame 210 does not surround the entire perimeter of the dust-removing sheet 208 but only seals off those portions that expose a potential path for dust and/or other particles to pass or get under the sheet 208.

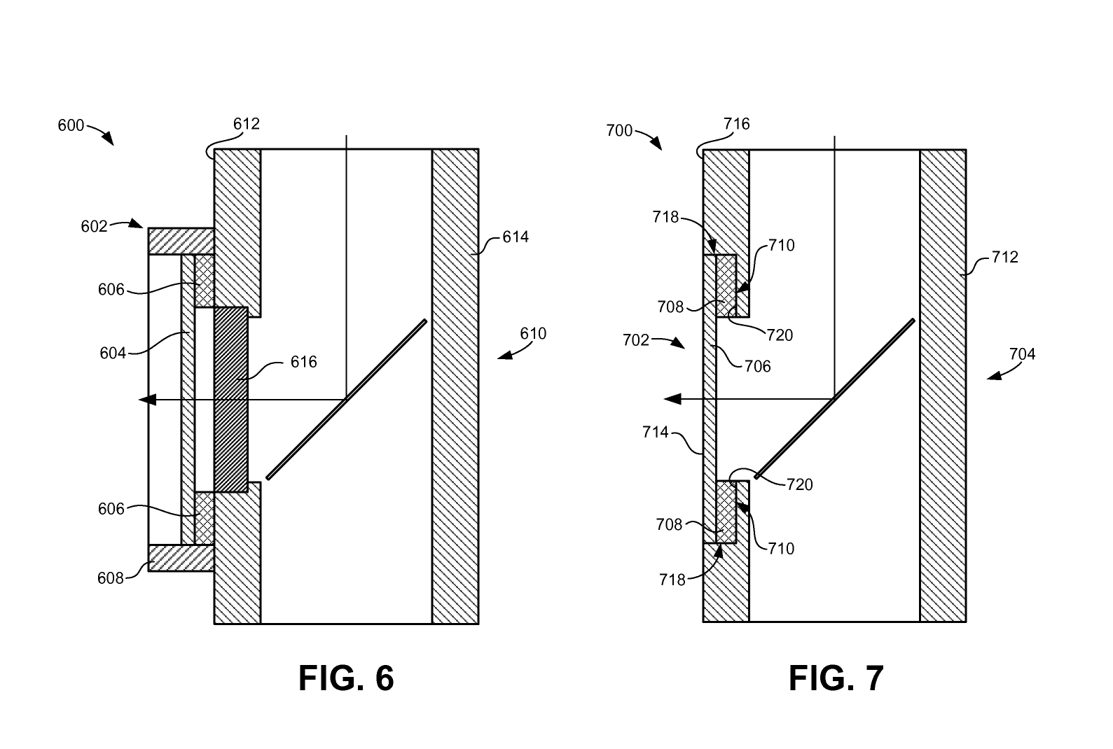

Additional examples constructed in accordance with teachings disclosed herein are shown and described in FIGS. 6 and 7. FIG. 6 is a cross-sectional view of an example system 600 that includes an example dust-removing apparatus 602. The example dust-removing apparatus 602 of FIG. 6 includes a transparent flexible sheet 604 affixed to two piezoelectric members 606 that cooperates with a frame 608 as described above to block dust from passing the sheet 604. In the illustrated example, the dust-removing apparatus 602 is affixed to an optical waveguide assembly 610. More particularly, as shown in the illustrated example, the piezoelectric members 606 of the dust-removing apparatus 602 are attached (e.g., via an adhesive) to an outer surface 612 of a housing 614 of the waveguide 610 such that the sheet 604 extends across an optical window 616 that is inset within the housing 614. Accordingly, the example of FIG. 6 does not necessitate any alterations to known optical waveguides (e.g., the optical waveguide assembly 102 of FIG. 1) thereby enabling the application of this example to existing optical network switches.

The example dust-removing apparatus 202 of FIGS. 2-5 differs from the example dust-removing apparatus 602 of FIG. 6 in that the piezoelectric members 606 of FIG. 6 have a smaller thickness than the piezoelectric members 206 of FIGS. 2-5. As a result of their reduced thickness, the piezoelectric members 606 of FIG. 6 are flush with the frame 604 against the outer surface 612 of the housing 614 as shown in FIG. 6, as opposed to mounted within the recess 214 as was done in the example of FIG. 4. In other examples, the piezoelectric members 202 of FIGS. 2-5 and the piezoelectric members 602 of FIG. 6 have the same thickness but the frame 608 has a greater thickness than the frame 210 to adequately extend beyond the sheet 604 to block dust from passing. In other examples, any or all of the sheet 604, the piezoelectric members 606 and the frame 608 of the dust-removing apparatus 602 are modified from the dust-removing apparatus 202 described above. For example, although the piezoelectric members 606 are shown in FIG. 6 as disposed immediately outside the edges of the optical window 616, in some examples, the piezoelectric members 606 are closer together such that the piezoelectric members 606 at least partially overlap the optical window 616. In other examples, the piezoelectric members 606 are placed farther apart. The height of the sheet 604 may be suitably modified to correspond to the distance between the piezoelectric members 606.

FIG. 7 is a cross-sectional view of another example system 700 constructed in accordance with the teachings disclosed herein. The example system 700 of FIG. 7 includes an example dust-removing apparatus 702 affixed to an optical waveguide assembly 704. In the illustrated example, the dust-removing apparatus 702 of the illustrated example comprises a dust-removing sheet 706 affixed (e.g., via an adhesive) to two piezoelectric members 708. In the illustrated example, the dust-removing apparatus 702 is disposed within a recess 710 of the housing 712 and physically dimensioned such that an outer surface 714 of the sheet 706 lies approximately flush with or within an outer surface 716 of the housing 712. In such examples, the dimensions of edges 718 of the recess 710 approximately correspond to the dimensions of the perimeter of the sheet 706 to seal the edges of the sheet 706. Accordingly, in the illustrated example of FIG. 7, a frame is not included because the housing 712 and sheet 706 cooperate to block dust and/or other particles from passing the sheet 706 in a similar manner to the frames 210, 616 described above in connection with FIGS. 2-6. In some examples, the dust-removing apparatus 702 is mounted to the housing 712 by affixing (e.g., via an adhesive) the piezoelectric members 708 to a back surface 720 of the recess 710.

Additionally, as shown in the illustrated example, the system 700 does not include an optical window because the dust-removing sheet 706 also functions as the optical window (e.g., to seal the waveguide while allowing optical signals to be transmitted through). In some examples, the optical windows 216, 610 are omitted in the corresponding dust-removing apparatus 202, 602 of FIGS. 2-6 because the sheets 208, 612 of the corresponding dust-removing apparatus 202, 602 cover the area of the optical windows 216, 610 and, therefore, can serve the purpose of the optical window. Thus, each of the sheets 208, 612 may be referred to as a window in this disclosure. Similarly, the window 216, 610 may cooperate with a respective sheet 208, 612. Thus, the combination of a window 216 and a sheet 208 may collectively be referred to as a window. Thus, as used herein, the term window is given to one or more of a single optical window and/or a combination of a sheet and a window.

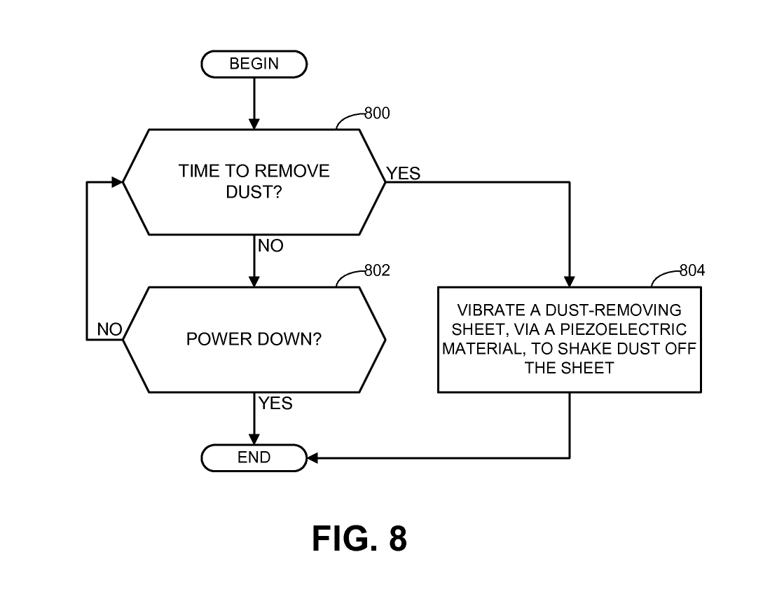

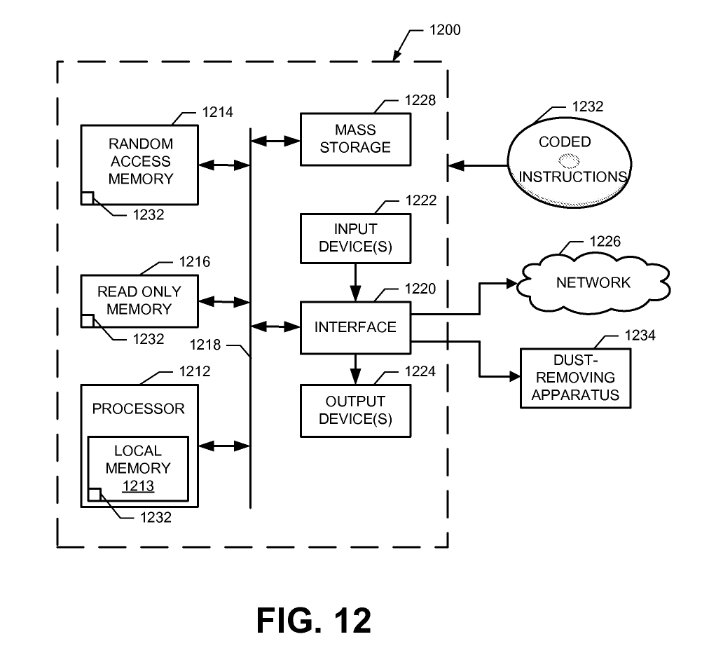

A flowchart representative of example machine readable instructions which may be executed to implement the example dust-removing apparatus 202, 602, 702 of FIGS. 2-7 is shown in FIG. 8. In this example, the machine readable instructions comprise a program for execution by a processor such as the processor 1212 shown in the example processor platform 1200 discussed below in connection with FIG. 12. The program may be embodied in software stored on a tangible computer readable medium such as a CD-ROM, a floppy disk, a hard drive, a digital versatile disk (DVD), a Blu-ray disk, or a memory associated with the processor 1212, but the entire program and/or parts thereof could alternatively be executed by a device other than the processor 1212 and/or embodied in firmware or dedicated hardware. Further, although the example program is described with reference to the flowchart illustrated in FIG. 8, many other methods of implementing the example dust-removing apparatus 202, 602, 702 may alternatively be used. For example, the order of execution of the blocks may be changed, and/or some of the blocks described may be changed, eliminated, or combined.

As mentioned above, the example process of FIG. 8 may be implemented using coded instructions (e.g., computer readable instructions) stored on a tangible computer readable medium such as a hard disk drive, a flash memory, a read-only memory (ROM), a compact disk (CD), a digital versatile disk (DVD), a cache, a random-access memory (RAM) and/or any other storage device and/or storage disc in which information may be stored for any duration (e.g., for extended time periods, permanently, brief instances, for temporarily buffering, and/or for caching of the information). As used herein, the term tangible computer readable medium is expressly defined to include any type of computer readable storage device and/or storage disc and to exclude propagating signals. Additionally or alternatively, the example process of FIG. 8 may be implemented using coded instructions (e.g., computer readable instructions) stored on a non-transitory computer readable medium such as a hard disk drive, a flash memory, a read-only memory, a compact disk, a digital versatile disk, a cache, a random-access memory and/or any other storage media in which information is stored for any duration (e.g., for extended time periods, permanently, brief instances, for temporarily buffering, and/or for caching of the information). As used herein, the term non-transitory computer readable storage medium is expressly defined to include any type of computer readable storage device and/or storage disc and to exclude propagating signals. As used herein, when the phrase “at least” is used as the transition term in a preamble of a claim, it is open-ended in the same manner as the term “comprising” is open ended. Thus, a claim using “at least” as the transition term in its preamble may include elements in addition to those expressly recited in the claim.

The example method of FIG. 8 begins with a processor (e.g., the processor 1212) determining whether it is time to remove dust from an optical connection (block 800). In some examples, the timing of removing dust from an optical connection is based on a schedule (e.g., every hour, every day, every month, etc.). In other examples, the time to remove dust is based on the processor receiving a user input requesting execution of the dust removal process (e.g., just before the user is to use the optical connection). If the processor determines it is not time to remove dust (block 800), the processor determines whether to power down (block 802). If the processor is to power down, the example process ends. If the processor determines that it is not to power down, control returns to block 800 where the processor determines whether it is time to clean.

If the processor determines that it is time to remove dust (block 800), the processor vibrates a dust-removing sheet (e.g., the dust-removing sheet 208 of FIG. 2) or window (e.g., the optical window 216), to shake dust off the sheet or window (block 800). In some examples, one or more piezoelectric elements are energized to vibrate the dust-removing sheet. Other examples use other types of vibration generating mechanisms and/or devices. In some examples, the dust-removing sheet covers an optical window (e.g., the optical window 216) of an optical waveguide assembly (e.g., the waveguide 204) to enable the removal of dust in the path of an optical signal. In some examples, the dust-removing sheet is the optical window. In some examples, the dust-removing apparatus is implemented on an optical waveguide assembly that is an optical backplane of a network switch chassis. Accordingly, in some examples, the method of FIG. 8 is initiated by a user before connecting a network blade (e.g., the network blade 104) to the optical waveguide. In this manner, any dust is removed just before the optical connector on the network blade engages the optical window to ensure a clear path for optical signals. Additionally, once the network blade and waveguide are interfacing, the concern with the accumulation of dust is alleviated.

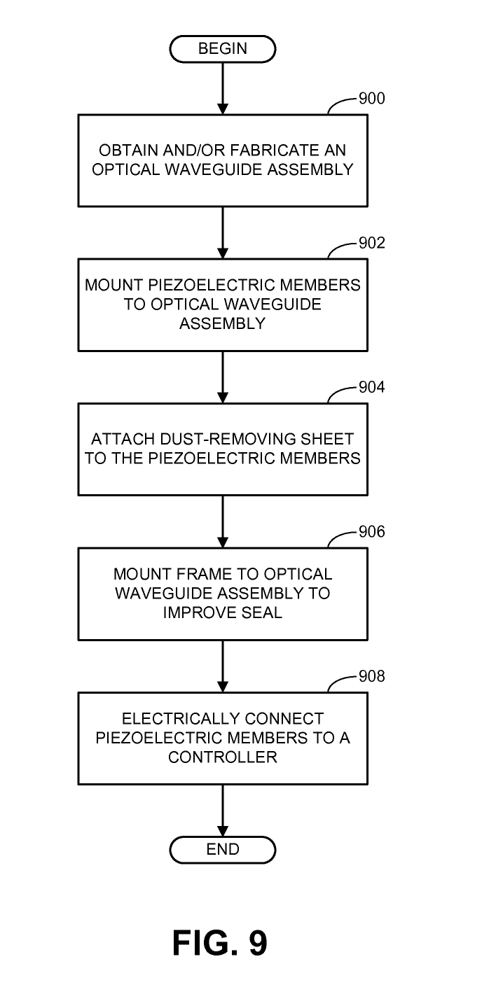

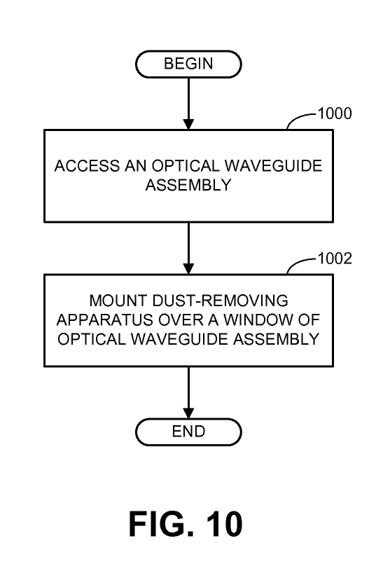

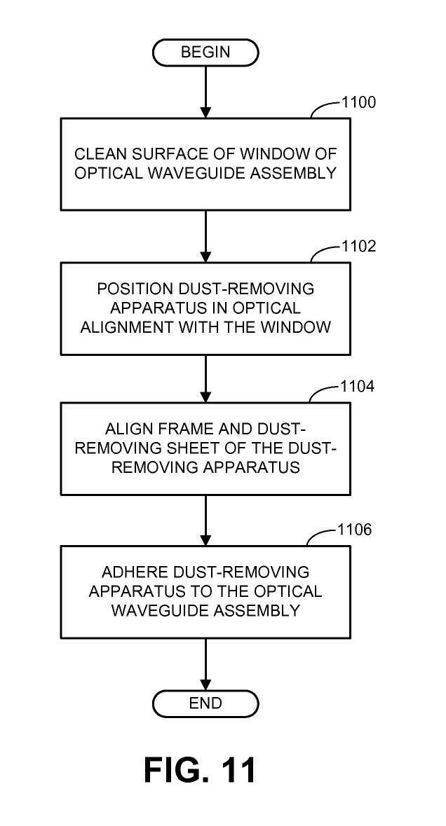

FIG. 9 is a flowchart representative of an example method of manufacturing the example systems 200, 600, 700 described in connection with FIGS. 2-7. FIG. 10 illustrates an example method to retrofit the dust-removing apparatus 202, 602, 702 of FIGS. 2-7 on to an existing waveguide assembly. FIG. 11 illustrates an example method detailing the mounting of the dust-removing apparatus 202, 602, 702 of FIGS. 2-7 on to a waveguide assembly. Other methods may be implemented to manufacture and/or retrofit the dust-removing apparatus. For example, one or more of the illustrated blocks in any of the example processes of FIGS. 9-11 may be combined, divided, re-arranged, omitted, eliminated and/or implemented in any other way).

Turning in detail to FIG. 9, the example process involves obtaining and/or fabricating an optical waveguide assembly (block 900) and mounting piezoelectric members to the optical waveguide assembly (block 902). In some examples, the piezoelectric members are mounted adjacent an optical window of the waveguide assembly. In some examples, two piezoelectric members are mounted adjacent opposing sides of the optical window. In some examples, the optical waveguide assembly includes a recess dimensioned to receive the piezoelectric members. In some such examples, the piezoelectric members are affixed to a back wall of the recess. In other examples, the piezoelectric members are mounted to an outer surface of the waveguide assembly. In some examples, the piezoelectric members are mounted to the optical waveguide assembly via an adhesive (e.g., an epoxy). In some examples, the piezoelectric members are configured to change shape under an electric signal primarily in the directions away from and towards the surface of the optical waveguide assembly on which the piezoelectric members are mounted.

The example process of FIG. 9 also includes attaching a dust-removing sheet to the piezoelectric members (block 904). In some examples, the sheet is attached to the piezoelectric members such that the sheet spans across an area through which an optical signal associated with the optical waveguide is to pass. In some examples, the area corresponds to an area over some or all of an optical window. In other examples, the portion of the sheet extending between the piezoelectric members is to be an optical window for an optical waveguide assembly. In some examples, the sheet is attached to the piezoelectric members via an adhesive (e.g., an epoxy).

The example process of FIG. 9 further includes mounting a frame to the optical waveguide assembly to improve the seal of the apparatus (block 906). In particular, the frame seals the apparatus to block dust from getting past the edges of the sheet. In some examples, the frame encloses or seals some of the edges of the sheet. For instance, in some examples, the frame encloses the free edges of the sheet (e.g., the edges not attached to the piezoelectric members). In other examples, the frame completely surrounds the perimeter of the sheet. In some examples, a frame is optional because the piezoelectric materials and the sheet are inset within a recess of an optical waveguide assembly. In such examples, the sides of the recess serve to enclose the edges of the sheet and block dust.

The example process of FIG. 9 includes electrically connecting the piezoelectric members to a controller (block 908). In this manner, the controller may transmit an electric signal to the piezoelectric members, thereby, causing the piezoelectric members to vibrate (e.g., change shape) and shake dust off the sheet. In some examples, the controller is integral to the frame. In other examples, the controller is separately mounted to the optical waveguide assembly. In some examples, the controller may be mounted to a printed circuit board (PCB). In some such examples, the frame and/or one or more of the piezoelectric members is also mounted to the PCB. In some examples, the piezoelectric members are connected in circuit with the controller via the PCB. In other examples, the piezoelectric members are connected to the controller via jumper wires. Once the piezoelectric members are electrically connected to the controller (block 908), the example process of FIG. 9 ends.

FIG. 10 illustrates a method of retrofitting an existing optical waveguide assembly with a dust-removing apparatus such as the apparatus of FIGS. 2-7. The example process of FIG. 10 involves accessing an optical waveguide assembly (block 1000). In some examples, the optical waveguide assembly is an existing waveguide fabricated in accordance with techniques known in the art. The example process further involves mounting a dust-removing apparatus over a window of the optical waveguide assembly (block 1002). More particularly, the dust-removing apparatus may be mounted to an outer surface of the optical waveguide assembly adjacent the window such that a dust-removing sheet of the dust-removing apparatus extends across the window. In this manner, the sheet may block dust from accumulating on the window and the dust-removing apparatus may shake the dust off the sheet as described above. Once the dust-removing apparatus is mounted over the window, the example process of FIG. 10 ends.

FIG. 11 is a flowchart representative of an example method detailing an example method of mounting the dust-removing apparatus on to a waveguide assembly of the example process of FIG. 10. The example process of FIG. 11 may implement block 1002 of FIG. 10 and involves cleaning the surface of a window of the optical waveguide assembly (block 1100). In this manner, dust and/or other particles obstructing the optical path of an optical signal will be removed prior to attaching the dust-removing apparatus. The example process also involves positioning the apparatus in optical alignment with the window (block 1102). In this manner, the dust-removing sheet of the dust-removing apparatus extends at least partially across the window to cover the window and protect the window from the accumulation of dust and/or other particles.

The example process of FIG. 11 further involves aligning the frame and the dust-removing sheet of the dust-removing apparatus (block 1104). In disclosed examples the frame serves to enclose and/or seal off one or more of the edges of the dust-removing sheet to block dust from passing the sheet and getting on the window. However, in some examples, the frame is positioned clear of the sheet to enable the sheet to freely vibrate when shaken by the piezoelectric members. In some examples, the sheet is mounted to the frame and the piezoelectric members vibrate the frame to remove dust from the sheet. In some examples the frame is tightly aligned with the sheet to block dust while allowing free movement of the sheet during operation. The example process also involves adhering the dust-removing apparatus to the optical waveguide assembly (block 1106). In some examples, the piezoelectric members and the frame of the dust-removing apparatus are separately adhered to the optical waveguide assembly to enable the free movement of the piezoelectric members (and, therefore, the dust-removing sheet) without interference from the frame. In some examples, the dust-removing apparatus is adhered to the optical waveguide assembly via an adhesive. Additionally or alternatively, any other suitable method of affixing the dust-removing apparatus to the optical waveguide may also be implemented. Once the dust-removing apparatus is adhered to the optical waveguide assembly, the example process of FIG. 11 ends.

FIG. 12 is a schematic illustration of an example processor platform 1200 that may be used and/or programmed to execute the example machine readable instructions of FIG. 8 to implement the example dust-removing apparatus 202, 602, 702 of FIGS. 2-7. The processor platform 1200 of the instant example includes a processor 1212. For example, the processor 1212 can be implemented by one or more microprocessors or controllers from any desired family or manufacturer.

The processor 1212 includes a local memory 1213 (e.g., a cache) and is in communication with a main memory including a volatile memory 1214 and a non-volatile memory 1216 via a bus 1218. The volatile memory 1214 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 1216 may be implemented by flash memory and/or any other desired type of memory device. Access to the main memory 1214 and 1216 is controlled by a memory controller.

The processor platform 1200 also includes an interface circuit 1220. The interface circuit 1220 may be implemented by any type of interface standard, such as an Ethernet interface, a universal serial bus (USB), and/or a PCI express interface. One or more input devices 1222 are connected to the interface circuit 1220. The input device(s) 1222 permit a user to enter data and commands into the processor 1212. The input device(s) can be implemented by, for example, a keyboard, a mouse, a touchscreen, a track-pad, a trackball, isopoint and/or a voice recognition system. One or more output devices 1224 are also connected to the interface circuit 1220. The output devices 1224 can be implemented, for example, by display devices (e.g., a liquid crystal display, a cathode ray tube display (CRT), a printer and/or speakers). The interface circuit 1220, thus, typically includes a graphics driver card.

The interface circuit 1220 also includes a communication device such as a modem or network interface card to facilitate exchange of data with external computers via a network 1226 (e.g., an Ethernet connection, a digital subscriber line (DSL), a telephone line, coaxial cable, a cellular telephone system, etc.).

The processor platform 1200 also includes one or more mass storage devices 1228 for storing software and data. Examples of such mass storage devices 1228 include floppy disk drives, hard drive disks, compact disk drives and digital versatile disk (DVD) drives.

Coded instructions 1232 to implement the example process of FIG. 8 may be stored in the mass storage device 1228, in the volatile memory 1214, in the non-volatile memory 1216, and/or on a removable storage medium such as a CD or DVD. More particularly, in the illustrated example, the interface circuit 1220 is in communication with a dust-removing apparatus 1234 (e.g., dust-removing apparatus 202, 602, 702 of FIGS. 2-7) such that the processor 1212 can provide instructions to vibrate and/or stop vibrating a dust-removing sheet and/or window as described above.

Although certain example methods, apparatus and articles of manufacture have been described herein, the scope of coverage of this patent is not limited thereto. On the contrary, this patent covers all methods, apparatus and articles of manufacture fairly falling within the scope of the claims of this patent.

What is claimed is:

1. An apparatus comprising:
a window to be located on an optical waveguide assembly; and
a first piezoelectric member coupled to the window, the first piezoelectric member to vibrate the window to remove dust from the window in response to an electrical signal.

2. The apparatus of claim 1, wherein the window comprises a first window and a transparent sheet, the transparent sheet has an inner surface facing the optical waveguide assembly, a first side of the first piezoelectric member to be affixed to the inner surface of the transparent sheet.

3. The apparatus of claim 2, wherein a second side of the first piezoelectric member opposite the first side of the first piezoelectric member is affixed to the optical waveguide assembly.

4. The apparatus of claim 2, wherein the first piezoelectric member is to vibrate in a direction substantially normal to the inner surface of the transparent sheet.

5. The apparatus of claim 1, wherein the window is inset within the optical waveguide assembly such that the optical waveguide assembly surrounds a perimeter of the window to block dust.

6. The apparatus of claim 1, further comprising a frame to be attached to the optical waveguide assembly, the frame to surround at least a portion of the window to block dust.

7. The apparatus of claim 1, wherein the window comprises a first window and a transparent sheet.

8. The apparatus of claim 1, further comprising a second piezoelectric member to be attached to the window, the first piezoelectric member attached adjacent a first edge of the window and the second piezoelectric member attached adjacent a second edge of the window.

9. The apparatus of claim 8, wherein the window comprises a transparent sheet, the optical waveguide assembly comprises a second window, the first and second piezoelectric members are located on opposing sides of the second window, the transparent sheet extends across the second window, and the first and second piezoelectric members are provided between the transparent sheet and the second window to create a clearance between the transparent sheet and the second window to allow the transparent sheet to vibrate.

10. An optical waveguide assembly comprising:
a housing;
a window carried by the housing;
a piezoelectric member carried by the housing; the piezoelectric member to vibrate in response to an electrical signal; and
a dust-removing sheet to vibrate in response to the piezoelectric member, the dust-removing sheet positioned adjacent the window to extend across an optical path of the optical waveguide assembly, the dust-removing sheet to vibrate with the piezoelectric material to shake dust off the optical path of the optical waveguide assembly.

11. The optical waveguide assembly of claim 10, wherein the piezoelectric member is disposed between the dust-removing sheet and the window, to create a gap between the dust-removing sheet and the optical waveguide assembly to allow the dust-removing sheet to vibrate.

12. A method comprising:
accessing an optical waveguide assembly defining an optical path; and
mounting a dust-removing apparatus to the optical waveguide and across the optical path, the dust-removing apparatus to be actuated to remove dust from the optical path.

13. The method of claim 12, wherein mounting the dust-removing apparatus comprises:
cleaning a surface of a window of the optical waveguide assembly;
positioning the dust-removing apparatus in optical alignment with the window, the dust-removing apparatus comprising a dust-removing sheet and a frame; and
adhering the dust-removing apparatus to the optical waveguide assembly.

14. The method of claim 12, wherein mounting the dust-removing apparatus comprises:
mounting piezoelectric members to the optical waveguide assembly;
attaching a dust-removing sheet to the piezoelectric members; and
electrically connecting the piezoelectric members to a controller.

15. The method of claim 14, wherein mounting the dust-removing apparatus further comprises mounting a frame to the optical waveguide assembly.
